(19) United States
(12) Patent Application Publication
(10) Pub. No.: US 2026/0113871 A1
(43) Pub. Date: Apr. 23, 2026

(54) COLD PLATE WITH PLASTIC BODY

(71) Applicant: Advanced Energy Industries, Inc., Denver, CO (US)

(72) Inventors: Ralford Garcia, Quezon City (PH); Paul Renan BAUI, Quezon City (PH); Iain Scott, Pasig City (PH)

(21) Appl. No.: 18/921,322

(22) Filed: Oct. 21, 2024

(51) Int. Cl. H05K 7/20; F28F 3/10

(52) U.S. Cl. CPC H05K 7/20254; F28F 3/10; F28F 2275/20

(57) ABSTRACT

A cold plate for cooling electronics comprises a first wall having a plurality of apertures formed therein, a second wall, and a plastic body positioned between the first and second walls and having at least one channel formed therein configured to pass a cooling fluid therethrough and wherein each aperture of the plurality of apertures is aligned with a respective portion of the at least one channel. A first gasket is positioned between the first wall and a first side of the plastic body, and a second gasket is positioned between the second wall and a second side of the plastic body. A port is coupled with the first wall and comprises an input channel and an output channel respectively coupled with the apertures of the plurality of apertures.

### TECHNICAL FIELD

Aspects of the disclosure relate to removing heat generated in electronic components, and more particularly to an improved design for a cold plate.

### BACKGROUND

During operation, an electronic component can generate heat that can become damaging to the electronic component if the temperature of the electronic component rises above a certain level. The temperature at which electronic components start to experience damage can vary between different types and even between different discrete components of the same type. Damage to the electronic component caused by too much heat can cause a loss of functionality either immediately or over time. Reducing the temperature of an electronic component can extend the component's life and can keep the component from heat-related damage.

Various methods exist to cool down electronic components subject to self-heating. Examples include operating the electronic component within a cold environment, using a fan to blow cooling air over the component, and conducting heat from the component into a heat sink. In one example, a combination of using a heat sink together with a fan blowing across fins of the heat sink can keep the generated heat below a level damaging to the component.

In another embodiment, the heat sink may include internal liquid cooling that causes a cooling fluid to flow through the heat sink to transport heat away from the component. The temperature of the cooling fluid may range from a level just below the temperature level damaging to the component to a level many degrees below 0 degrees C. For example, some gases in their liquid form may be used as cooling fluids.

In one existing cold plate design, a slab of solid aluminum block is machined to form one or more channels into which copper piping is pressed. The copper piping serves as the container for the cooling flow and is bent (e.g., sometimes multiple times) according to the design of the channel and then pressed into the channel. A thermal epoxy is added to secure the copper pipe to the aluminum channel. The aluminum, thermal epoxy, copper pipe, and cooling fluid serve to transport heat away from an electronic component in thermal contact with the cold plate. The electronic component is often glued to or pressed against the cold plate, whether directly or through other substrates such as a printed circuit board.

The aluminum block/copper pipe cold plate design, however, has limited performance due to the aluminium/copper interface, flow rate and routing limitations, can be cost prohibitive and can be relatively heavy. It would, therefore, be advantageous to have an improved design for a cold plate capable of removing heat from a desired electronic component that overcomes the aforementioned drawbacks.

### SUMMARY

In accordance with one aspect of the present disclosure, a cold plate for cooling electronics comprises a first wall having a plurality of apertures formed therein, a second wall, and a plastic body positioned between the first and second walls and having at least one channel formed therein configured to pass a cooling fluid therethrough and wherein each aperture of the plurality of apertures is aligned with a respective portion of the at least one channel. A first gasket is positioned between the first wall and a first side of the plastic body, and a second gasket is positioned between the second wall and a second side of the plastic body. A port is coupled with the first wall and comprises an input channel and an output channel respectively coupled with the apertures of the plurality of apertures.

In accordance with another aspect of the present disclosure, a method of manufacturing a cold plate comprises aligning a first plate with a synthetic form, wherein a first gasket material is positioned between the first plate and the synthetic form. A second plate is aligned with the synthetic form, wherein a second gasket material positioned between the second plate and the synthetic form. The method also comprises coupling the first plate, the second plate, and the synthetic form together and coupling a fluid port to the first plate. The fluid port comprises an input channel fluidly coupled with an input aperture formed in the first plate and comprises an output channel coupled with an output aperture formed in the first plate. The synthetic form has at least one channel formed therein to allow a cooling fluid to flow therethrough from the input channel to the output channel.

### BRIEF DESCRIPTION OF THE DRAWINGS

The drawings illustrate embodiments presently contemplated for carrying out the invention.

In the drawings:

FIG. 1 illustrates a cold plate according to aspects of this disclosure.

FIG. 2 illustrates an exploded view of the cold plate of FIG. 1 according to aspects of this disclosure.

FIG. 3 illustrates a first view of the synthetic body of the cold plate of FIG. 1 according to aspects of this disclosure.

FIG. 4 illustrates a second view of the synthetic body of the cold plate of FIG. 1 according to aspects of this disclosure.

FIG. 5 illustrates an exploded view of the port of FIG. 1 according to aspects of this disclosure.

FIG. 6 illustrates an alternative synthetic body of the cold plate of FIG. 1 according to aspects of this disclosure.

FIG. 7 illustrates an alternative synthetic body of the cold plate of FIG. 1 according to aspects of this disclosure.

While the present disclosure is susceptible to various modifications and alternative forms, specific embodiments thereof have been shown by way of example in the drawings and are herein described in detail. It should be understood, however, that the description herein of specific embodiments is not intended to limit the present disclosure to the particular forms disclosed, but on the contrary, the intention is to cover all modifications, equivalents, and alternatives falling within the spirit and scope of the present disclosure. Note that corresponding reference numerals indicate corresponding parts throughout the several views of the drawings.

### DETAILED DESCRIPTION

Examples of the present disclosure will now be described more fully with reference to the accompanying drawings. The following description is merely exemplary in nature and is not intended to limit the present disclosure, application, or uses.

Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

Although the disclosure hereof is detailed and exact to enable those skilled in the art to practice the invention, the physical embodiments herein disclosed merely exemplify the invention which may be embodied in other specific structures. While the preferred embodiment has been described, the details may be changed without departing from the invention, which is defined by the claims.

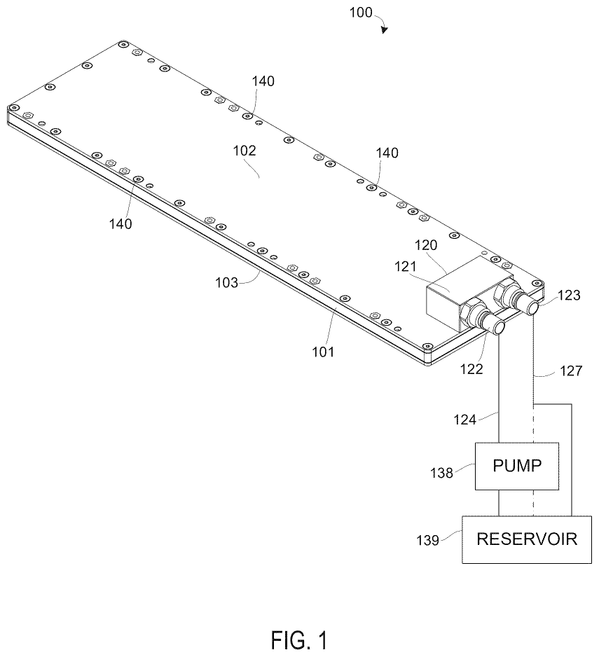

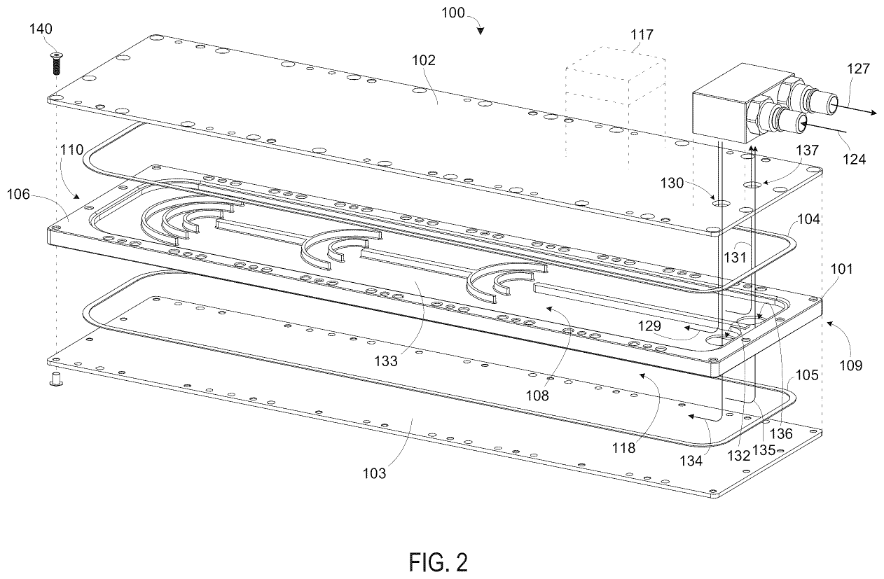

Referring to FIGS. 1 and 2, a cold plate 100 is illustrated according to aspects of this disclosure. A synthetic form or body 101 is aligned and positioned between a first wall or plate 102 and a second wall or plate 103. In one embodiment, the synthetic form 101 is constructed of plastic, and the first and second walls 102, 103 are constructed of a thermally conductive material such as a metal or alloy. For example, the walls 102, 103 may be made of an aluminum or copper plate. A gasket material is used to form first and second gaskets 104, 105 to create a fluid seal between the synthetic form 101 and the walls 102, 103. In a preferred embodiment, the gaskets 104, 105 are formed via a form-in-place gasket material configured to provide long term sealing reliability. For example, a liquid gasket material is dispensed onto the synthetic form 101 and/or the walls 102, 103 prior to assembly. The liquid gasket material conforms to the form and to any imperfections in the synthetic form 101 and/or the walls 102, 103 and yields a reliable and durable seal for cooling fluid flowing through the cold plate 100.

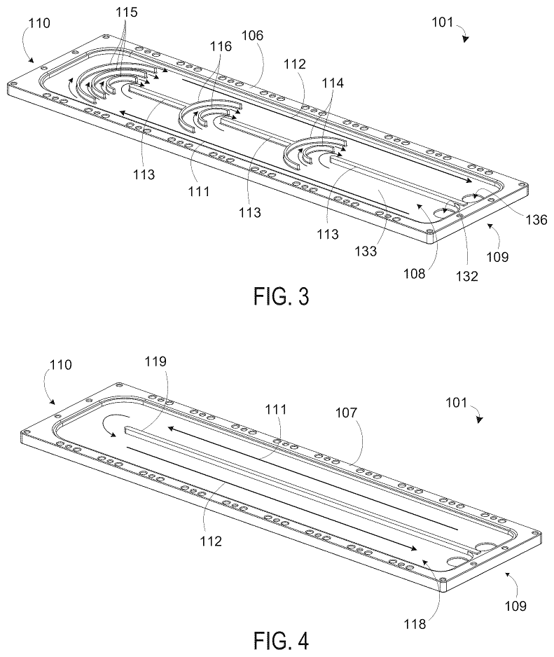

A first side 106 of the synthetic form 101 is shown in FIGS. 2 and 3, and a second side 107 of the synthetic form 101 is shown in FIG. 4 according to an example. Referring to FIGS. 2 and 3, the synthetic form 101 has a channel 108 formed in the first side 106 of the synthetic form 101. The channel 108 has a complex shape determined from fluid flow and heat transfer considerations that extends from a first end 109 of the synthetic form 101 toward a second end 110 and back toward the first end 109. For example, with reference to the simpler channel on side 107 in FIG. 4 that is also derived from flow and heat transfer considerations, arrow 111 illustrates a direction of a channel 118 extending from the first end 109 toward the second end 110. Arrow 112 illustrates a direction of the channel 118 extending from the second end 110 toward the first end 109.

A center wall 113 formed in the first side 106 separates portions of the channel 108 and guides cooling fluid flowing through separate portions of the channel. As shown, cooling fluid flowing through the channel 108 is not restricted to flowing the complete distance between the first and second ends 109, 110 of the synthetic form 101. Breaks in the center wall 113, together with a plurality of flow directors, provide shortcut paths that allow the cooling fluid to return to the first side 106 at one or more earlier portions of the channel 108 than the portion adjacent to the second end 110. For example, a pair of flow directors 114 provide a return path for a first portion of the cooling fluid sooner than a return path provided by flow directors 115 adjacent to the second end 110. A remaining portion of the cooling fluid, however, flows past the flow directors 114 and on toward the second end 110. Another set of flow directors 116 may further divide the cooling flow prior to reaching the second end 110 and the flow directors 115.

Based on a position of electronic components adjacent to the cold plate 100 described herein, it may be desirable to provide directed or focused cooling for one or more of the electronic components. By strategically designing and placing the flow directors 114-116, portions of the cooling fluid having a lower temperature can be directed toward the heat transfer location of the desired electronic components (e.g., component 117 shown in phantom in FIG. 2). For example, the portion of the cooling fluid redirected by the flow directors 114 will provide a colder cooling fluid to the section on the other side of the center wall 113 and adjacent to the component 117 than the remainder of the cooling fluid allowed to flow past the flow directors 114 to be guided by flow directors 115 or 116 on a longer flow path back toward the first end 109.

Referring to FIG. 4, the second channel 118 is shown formed in the second side 107 of the synthetic form 101 to provide a flow path for the cooling fluid on an opposite side of the synthetic form 101. The center wall 119 formed in the synthetic form 101 on the second side 107 illustrates another embodiment absent of any intermediary breaks therein. In this manner, a single flow path for the cooling fluid exists from the first end 109 toward the second end 110 and back toward the first end 109.

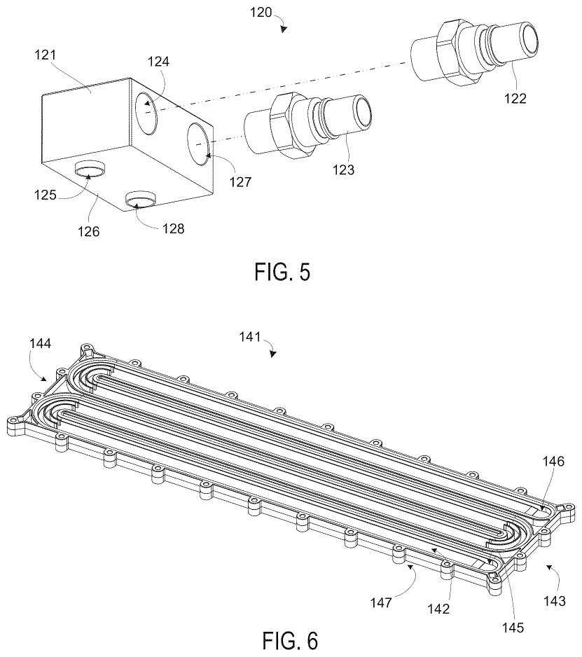

Referring back to FIG. 1, a fluid port 120 is attached to the first wall 102 to allow cooling fluid to enter and exit the interior volume of the cold plate 100. FIG. 5 illustrates an exploded view of the fluid port 120 according to aspects of this disclosure. As shown in FIGS. 1 and 5, the fluid port 120 includes a port body 121 with a pair of port connectors 122, 123 coupled thereto. As described herein, the port connector 122 corresponds with an input side of the fluid port 120, and the port connector 123 corresponds with an output side of the fluid port 120. An input channel 124 formed in the port body 121 allows a cooling fluid transmitted to the port body 121 via the port connector 122 to flow out an input aperture 125 formed in the cold plate side 126 of the fluid port 120. An output channel 127 allows the cooling fluid to exit the cold plate 100 through an output aperture 128. The fluid port 120 is positioned adjacently to the first wall 102 and fixed in place so that cooling fluid flows between the input channel 124, the channels 108/118 of the synthetic form 101, and the output channel 127. In one embodiment, the port body 121 is welded to the first wall 102. In another embodiment, the port body 121 is brazed to the first wall 102. Other methods for attaching the port body 121 to the first wall 102 are also within the scope of this disclosure.

As shown in FIG. 2, a first portion of cooling fluid flows along path 129 from the input channel 124 of the fluid port 120, through a plate aperture 130 formed in the first wall 102, and into a first portion of the channel 108 to provide cooling to one or more electronic components in thermal contact with the first wall 102. The first portion of the cooling fluid returns along path 131 to a second portion of the channel 108 and to the output channel 127. A second portion of cooling fluid passes through a channel aperture 132 formed in a center portion 133 of the synthetic form 101 along path 134 from the input channel 124 of the fluid port 120 and into a first portion of the channel 118 to provide cooling to one or more electronic components in thermal contact with the second wall 103. The second portion of the cooling fluid returns along path 135 through a second portion of the channel 118 and through another channel aperture 136 and a plate aperture 137 to the output channel 127. The plate apertures 130, 137 are aligned with the channel 108 to provide cooling fluid flow between the channel 108 and the fluid port 120. The plate apertures 130, 137 may also be aligned with the channel apertures 132, 136.

In one embodiment, as illustrated in FIG. 1, cooling fluid may be directed to the cold plate 100 via a pump 138 configured to draw the cooling fluid from a reservoir 139. As shown, the cooling fluid exiting the cold plate 100 via the output channel 127 may be returned to the reservoir 139 directly or via passing again through the pump 138. As further illustrated, a plurality of fasteners 140 (e.g., screws) may be used to secure and fasten the walls 102, 103 and the synthetic form 101 together.

FIG. 6 illustrates an alternative plastic body 141 of the cold plate 100 of FIG. 1 according to aspects of this disclosure. A channel 142 formed therein causes cooling fluid flowing therethrough to flow toward the opposite ends 143, 144 four times along the serpentine shape. Channel apertures 145, 146 allow a portion of the cooling fluid to flow through a second channel 147 formed on a second side of the plastic body 141. The shape of the fluid channels 142, 147 may be different as needed based on the cooling needs of each side of the cold plate 100. Based on the distinct design of the channel 142 in the plastic body 141 compared with the design of the channel 108 of the synthetic form 101 (as illustrated in FIG. 2), the location and spacing of the plate apertures 130, 137 and the input and output channels 124, 127 will vary from that illustrated herein to accommodate the different locations of the beginning and ending of the channel 142.

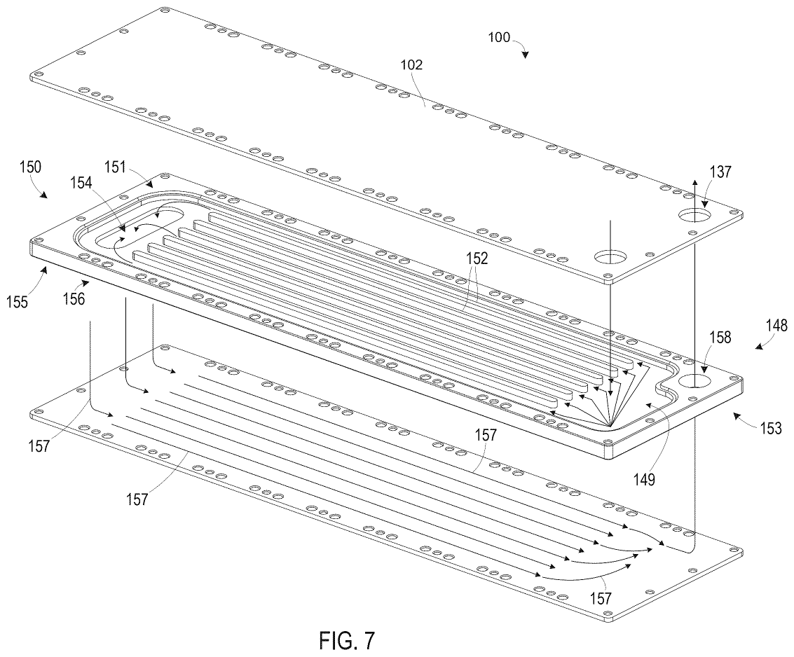

FIG. 7 illustrates an alternative plastic body 148 of the cold plate 100 of FIG. 1 according to aspects of this disclosure. A first channel 149 formed therein causes cooling fluid flowing therethrough to flow toward an opposite end 150 of the first, input side first side 151 of the plastic body 148. A plurality of walls 152 (e.g., six walls as illustrated in FIG. 7) extends in a direction between the ends 150, 153 of the plastic body 148. An opening 154 formed in the plastic body 148 near the opposite end 150 allows the cooling fluid to flow to the opposite side 155 of the plastic body 148 and through a second channel 156 formed therein. A second plurality of walls (not shown) formed in the second channel 156 direct flow of the cooling fluid back toward the first end 153. Exemplary flow arrows 157 illustrated adjacent to the second wall 103 indicate the flow of the cooling fluid through the second channel 156. Return of the cooling fluid to the fluid port 120 (FIG. 1) passes through a channel aperture 158 and the wall aperture 137.

Embodiments of the cold plate described herein have advantages such allowing for a thinner cold plate made of less-expensive parts that does not require milling out fluid channels in a thick block of metal. The flow directors formed in the synthetic body provide specific locations (which can be multiple) of targeted cooling. The flow directors, channels, and walls illustrated and discussed herein are exemplary designs showing the versatility of the disclosed cold plate and are not intended to restrict the designs or configurations possible based on this disclosure. The double-sided design also improves packaging density and increases the cooling surface area.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the present disclosure. Additionally, while various embodiments of the present disclosure have been described, it is to be understood that aspects of the present disclosure may include only some of the described embodiments. Accordingly, the invention is not to be seen as limited by the foregoing description but is only limited by the scope of the appended claims.

What is claimed is:

1. A cold plate for cooling electronics, the cold plate comprising:
a first wall having a plurality of apertures formed therein;
a second wall;
a plastic body positioned between the first and second walls and having at least one channel formed therein configured to pass a cooling fluid therethrough and wherein each aperture of the plurality of apertures is aligned with a respective portion of the at least one channel;
a first gasket positioned between the first wall and a first side of the plastic body;
a second gasket positioned between the second wall and a second side of the plastic body; and
a port coupled with the first wall and comprising an input channel and an output channel respectively coupled with the apertures of the plurality of apertures.

2. The cold plate of claim 1, wherein the first and second gaskets comprise a form-in-place gasket material.

3. The cold plate of claim 1, wherein the at least one channel of the plastic body comprises a first channel formed in the first side of the plastic body and having a first portion aligned with a first aperture of the plurality of apertures and having a second portion aligned with a second aperture of the plurality of apertures.

4. The cold plate of claim 3, wherein the at least one channel of the plastic body comprises a second channel formed in the second side of the plastic body;
wherein the second channel is fluidly coupled with the first channel.

5. The cold plate of claim 4, wherein the plastic body comprises:
a first channel aperture formed in the plastic body configured to fluidly couple the first portion of the first channel with a first portion of the second channel; and
a second channel aperture formed in the plastic body configured to fluidly couple the second portion of the first channel with a second portion of the second channel.

6. The cold plate of claim 5, wherein a first portion of the cooling fluid is configured to flow from the input channel through the first channel toward the output channel; and
wherein a remaining portion of the cooling fluid is configured to flow from the input channel through the first aperture and through the second channel toward the second aperture and the output channel.

7. The cold plate of claim 5, wherein the first channel aperture is aligned with the first aperture; and
wherein the second channel aperture is aligned with the second aperture.

8. The cold plate of claim 1, wherein the port is welded to the first wall.

9. The cold plate of claim 1, wherein the port is brazed to the first wall.

10. The cold plate of claim 1, wherein the plastic body comprises one or more flow directors formed within the at least one channel configured to divide the cooling fluid into a plurality of flow streams; and
wherein a first flow stream of the plurality of flow streams is directed toward a predetermined location of the first wall.

11. The cold plate of claim 1 further comprising a plurality of fasteners inserted through fastener openings formed in the first wall, the second wall, and the plastic body to couple the first wall, the second wall, and the plastic body together.

12. The cold plate of claim 1, wherein each of the first and second walls comprises a plate of thermally conductive material.

13. A method of manufacturing a cold plate, the method comprising:
aligning a first plate with a synthetic form, wherein a first gasket material is positioned between the first plate and the synthetic form;
aligning a second plate with the synthetic form, wherein a second gasket material positioned between the second plate and the synthetic form;
coupling the first plate, the second plate, and the synthetic form together;
coupling a fluid port to the first plate;
wherein the fluid port comprises an input channel fluidly coupled with an input aperture formed in the first plate and comprises an output channel coupled with an output aperture formed in the first plate;
wherein the synthetic form has at least one channel formed therein to allow a cooling fluid to flow therethrough from the input channel to the output channel.

14. The method of claim 13 further comprising:
forming a first gasket via the first gasket material, wherein the first gasket material comprises a form-in-place gasket material; and
forming a second gasket material via the second gasket material, wherein the second gasket material comprises the form-in-place gasket material.

15. The method of claim 13 further comprising:
forming a first channel of the at least one channel in a first side of the synthetic form; and
forming, within the first channel, one or more flow directors configured to divide the cooling fluid into a plurality of flow streams within the first channel.

16. The method of claim 15 further comprising:
forming a second channel of the at least one channel in a second side of the synthetic form; and
forming a pair of apertures through a center portion of the synthetic form to fluidly couple the first channel with the second channel.

17. The method of claim 16 further comprising forming, within the second channel, at least one additional flow director configured to divide the cooling fluid into a plurality of flow streams within the second channel.

18. The method of claim 13, wherein coupling the fluid port to the first plate comprises one of brazing the fluid port to the first plate and welding the fluid port to the first plate.

19. The method of claim 13, wherein forming the first channel comprises forming a serpentine channel configured to direct the flow of the cooling fluid toward a first end of the synthetic form and toward a second end of the synthetic form multiple times.

20. The method of claim 13, wherein the synthetic form comprises plastic.
